(19) United States
(12) Patent Application Publication
(10) Pub. No.: US 2011/0174370 A1
(43) Pub. Date: Jul. 21, 2011

(54) THIN FILM SOLAR CELL AND MANUFACTURING METHOD THEREOF

(75) Inventor: Chin-Yao Tsai, Tainan (TW)

(73) Assignee: AURIA SOLAR CO., LTD., Tainan (TW)

(21) Appl. No.: 13/049,688

(22) Filed: Mar. 16, 2011

(30) Foreign Application Priority Data
Mar. 17, 2010 (TW) 099107827

(51) Int. Cl. H01L 31/0232; H01L 31/18

(52) U.S. Cl. 136/256; 438/71; 257/E31.13

(57) ABSTRACT

A thin film solar cell includes a transparent substrate, a first transparent conductive layer, a photovoltaic layer, a second transparent conductive layer, a first adhesive layer and a reflective layer is provided. The first transparent conductive layer is disposed on a back surface of the transparent substrate. The photovoltaic layer is disposed on the first transparent conductive layer. The second transparent conductive layer is disposed on the photovoltaic layer. The first adhesive layer is disposed on the second transparent conductive layer. The reflective layer is disposed on the first adhesive layer. The surface of the first adhesive layer in contact with the reflective layer is a texture structure. The light beam passing the first adhesive layer is reflected by the texture structure or the reflective layer and transmitted back to the photovoltaic layer, and the wavelength range of the reflected light beam is substantially between 600 nm and 1,100 nm.

### CROSS-REFERENCE TO RELATED APPLICATIONS

This non-provisional application claims priority under 3535 U.S.C. §119(a) on Patent Application No. 099107827 filed in Taiwan, R.O.C. on Mar. 17, 2010, the entire contents of which are hereby incorporated by reference.

### BACKGROUND OF THE INVENTION

1. Field of Invention

The present invention relates to a solar cell and a manufacturing method thereof, and more particularly to a thin film solar cell with higher photoelectric conversion efficiency and a manufacturing method thereof.

2. Description of Related Art

Solar cells have drawn attention in many alternative energy and renewable energy technologies. The main reason is that solar cells can collect electricity directly from sunlight, and carbon dioxide, nitride gas or pernicious gases are not generated during the electricity generation process, so that the environment is not polluted. In various solar cells, a thin film solar cell has strong development potential due to the advantage of low process cost thereof.

Generally speaking, in a conventional thin film solar cell, an electrode layer, a photovoltaic layer and another electrode layer are sequentially blanket-stacked on a substrate. When the light enters the thin film solar cell from outside, free electron-hole pairs are generated in the photovoltaic layer by the solar energy, and the internal electric field formed by the PN junction makes electrons and holes respectively move toward two layers, so as to generate a storage state of electricity. Meanwhile, if a load circuit or an electronic device is connected, the electricity can be provided to drive the circuit or device.

However, the average photoelectric conversion efficiency of the current thin film solar cell is about 6-10% mainly due to the lower light utilization rate. The light path of the light passing the photovoltaic layer is limited by the thickness of the photovoltaic layer, so that the light can not be effectively absorbed. Specially, the light with wavelengths greater than the red light range is difficult to be utilized effectively.

### SUMMARY OF THE INVENTION

The present invention provides a thin film solar cell to enhance the light utilization rate and further improve the photoelectric conversion efficiency.

The present invention provides a manufacturing method to form the above-mentioned thin film solar cell.

The present invention provides a thin film solar cell including a transparent substrate, a first transparent conductive layer, a photovoltaic layer, a second transparent conductive layer, a first adhesive layer and a reflective layer. The transparent substrate has a light incident surface and a back surface opposite to the light incident surface. The first transparent conductive layer is disposed on the back surface of the transparent substrate. The photovoltaic layer is disposed on the first transparent conductive layer. The second transparent conductive layer is disposed on the photovoltaic layer. The first adhesive layer is disposed on the second transparent conductive layer. The reflective layer is disposed on the first adhesive layer. The surface of the first adhesive layer in contact with the reflective layer is a texture structure. A light beam enters the thin film solar cell through the light incident surface, sequentially passes the transparent substrate, the first transparent conductive layer, the photovoltaic layer and the second transparent conductive layer and reaches the first adhesive layer. The light beam passing the first adhesive layer is reflected by the texture structure or the reflective layer and transmitted back to the photovoltaic layer, and the wavelength range of the reflected light beam is substantially between 600 nm and 1,100 nm.

According to an embodiment of the present invention, the thin film solar cell further includes a second adhesive layer and an opposite substrate. The second adhesive layer is disposed on the reflective layer. The opposite substrate is disposed on the second adhesive layer and opposite to the transparent substrate.

According to an embodiment of the present invention, the reflective layer is conformal to the texture structure.

According to an embodiment of the present invention, the shape of the texture structure includes a vertical-stripe shape, a stripe shape, a horizontal-stripe shape, a grid shape, a rhombus shape, a honeycomb shape or a mosaic shape.

According to an embodiment of the present invention, the texture structure is a regular or irregular arrangement.

According to an embodiment of the present invention, the material of the adhesive layer includes ethylene vinyl acetate (EVA), polyvinyl butyral (PVB), poly olefin or polyurethane (PU).

According to an embodiment of the present invention, the thin film solar cell further includes a plurality of particles distributed therein, and a portion of the light beam is reflected by the particles and transmitted back to the photovoltaic layer.

According to an embodiment of the present invention, the wavelength range of the portion of the light beam reflected by the particles is substantially between 600 nm and 1,100 nm.

According to an embodiment of the present invention, the thickness of the first adhesive layer is between 0.5 mm and 5 mm.

According to an embodiment of the present invention, the material of the reflective layer includes one or more materials selected from the group consisting of a lead paint, a metal, a metal oxide and an organic material.

According to an embodiment of the present invention, the reflected light beam includes a red light, a near-infrared light or a far-infrared light.

According to an embodiment of the present invention, the photovoltaic layer is a single-layer light absorption layer, a double-layer light absorption layer, a triple-layer light absorption layer or a multiple-layer light absorption layer.

The present invention further provides a manufacturing method of a thin film solar cell. A transparent substrate having a light incident surface and a back surface opposite to the light incident surface is provided. A first transparent conductive layer is formed on the back surface of the transparent substrate. A photovoltaic layer is formed on the first transparent conductive layer. A second transparent conductive layer is formed on the photovoltaic layer. A first adhesive layer having a texture structure is formed on the second transparent conductive layer. A reflective layer is formed on the first adhesive layer covering the texture structure. A light beam passing the first adhesive layer is reflected by the texture structure or the reflective layer and transmitted back to the photovoltaic layer, and the wavelength range of the reflected light beam is substantially between 600 nm and 1,100 nm.

According to an embodiment of the present invention, the manufacturing method further includes forming a second adhesive layer on the reflective layer; and disposing an opposite substrate on the second adhesive layer to package the transparent substrate and the opposite substrate.

According to an embodiment of the present invention, the method of forming the first adhesive layer on the second transparent layer includes a stamping process.

According to an embodiment of the present invention, the stamping process includes the following steps. An adhesive material layer is formed on the second transparent conductive layer. A die having a texture pattern is stamped on the adhesive material layer so as to form the first adhesive layer having the texture structure.

According to an embodiment of the present invention, the method of forming the first adhesive layer on the second transparent conductive layer includes the following steps. An adhesive material layer is provided. A die having a texture pattern is stamped on the adhesive material layer, so as to form the texture structure on a surface of the adhesive material layer, thereby obtaining the first adhesive layer. The first adhesive layer is disposed on the second transparent conductive layer.

According to an embodiment of the present invention, the method of forming the first adhesive layer on the second transparent conductive layer includes a mesh process including the following steps. A die having a mesh pattern is disposed on the second transparent conductive layer, wherein the mesh pattern has a plurality of openings exposing the second transparent conductive layer. An adhesive material layer is formed on the die, wherein a portion of the adhesive material layer fills the openings in contact with the second transparent conductive layer. The die is removed to form the first adhesive layer having the texture structure.

The present invention also provides a thin film solar cell including a transparent substrate, a first transparent conductive layer, a photovoltaic layer, a second transparent conductive layer, a light reflective layer and a substrate. The transparent substrate has a light incident surface and a back surface opposite to the light incident surface. The first transparent conductive layer is disposed on the back surface of the transparent substrate. The photovoltaic layer is disposed on the first transparent conductive layer. The second transparent conductive layer is disposed on the photovoltaic layer. The substrate has a surface with a texture structure thereon, wherein the light reflective layer is disposed on the surface and conformal to the texture structure, and the light reflective layer is disposed between the second transparent conductive layer and the substrate. When a light beam enters the thin film solar cell through the light incident surface, sequentially passes the transparent substrate, the first transparent conductive layer, the photovoltaic layer and the second transparent conductive layer and reaches the light reflective layer on the texture structure, at least a portion of the light beam having a wavelength range substantially between 600 nm and 1,100 nm is reflected by the light reflective layer on the texture structure.

According to an embodiment of the present invention, the material of the substrate includes a transparent material or a non-transparent material.

According to an embodiment of the present invention, the thin film solar cell further includes an adhesive layer disposed between the light reflective layer and the second transparent conductive layer so as to package the thin film solar cell. In an embodiment, the material of the adhesive layer includes ethylene vinyl acetate (EVA), polyvinyl butyral (PVB), poly olefin or polyurethane (PU).

According to an embodiment of the present invention, the material of the light reflective layer includes one or more materials selected from the group consisting of a lead paint, a metal, a metal oxide and an organic material. In an embodiment, the metal is selected from the group consisting of aluminium (Al), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), lanthanum (La), gadolinium (Gd), hafnium (Hf), tantalum (Ta), tungsten (W), rhenium (Re), osmium (Os), iridium (Ir), platinum (Pt), gold (Au), thallium (Tl), lead (Pb) and combinations thereof. In an embodiment, the metal oxide is selected from the group consisting of indium oxide, tin oxide, silicon oxide, magnesium fluoride, tantalum oxide, titanium oxide, magnesium oxide, zirconium oxide, silicon nitride, aluminium oxide, hafnium oxide, Indium tin oxide (ITO), Cd₂SnO₄, Cd₂SnO₄ doped with copper, stannic oxide and stannic oxide doped with fluorine. In an embodiment, the organic material can be a white dye or pigment.

According to an embodiment of the present invention, the photovoltaic layer is a Group IV thin film, a III-V compound semiconductor thin film, a II-VI compound semiconductor thin film or an organic compound semiconductor thin film. In an embodiment, the Group IV thin film is at least one of an amorphous silicon (a-Si) thin film, a microcrystalline silicon (μc-Si) thin film, an amorphous silicon germanium (a-SiGe) thin film, a microcrystalline silicon germanium (μc-SiGe) thin film, an amorphous silicon carbide (a-SiC) thin film, a microcrystalline silicon carbide (μc-SiC) thin film, a tandem I-V thin film and a triple I-V thin film.

The present invention further provides a thin film solar cell including a transparent substrate, a first transparent conductive layer, a photovoltaic layer, a second transparent conductive layer and a substrate. The transparent substrate has a light incident surface and a back surface opposite to the light incident surface. The first transparent conductive layer is disposed on the back surface of the transparent substrate. The photovoltaic layer is disposed on the first transparent conductive layer. The substrate has a surface with a texture structure thereon. The second transparent conductive layer is disposed between the photovoltaic layer and the substrate. When a light beam enters the thin film solar cell through the light incident surface, sequentially passes the transparent substrate, the first transparent conductive layer, the photovoltaic layer and the second transparent conductive layer and reaches the texture structure, at least a portion of the light beam having a wavelength range substantially between 600 nm and 1,100 nm is reflected by the texture structure.

According to an embodiment of the present invention, the material of the substrate includes a transparent material or a reflective material.

According to an embodiment of the present invention, the thin film solar cell further includes an adhesive layer disposed between the second transparent layer and the photovoltaic layer, so as to package the thin film solar cell. In an embodiment, when the substrate is a transparent material, a refractive index of the substrate is smaller than that of the adhesive layer. In an embodiment, the material of the adhesive layer includes ethylene vinyl acetate (EVA), polyvinyl butyral (PVB), poly olefin or polyurethane (PU).

According to an embodiment of the present invention, the portion of the light beam includes a red light, a near-infrared light or a far-infrared light.

In view of the above, the thin film solar cell of the present invention has a first adhesive layer and a reflective layer, and the surface of the first adhesive layer in contact with the reflective layer has a texture structure to reflect the light beam. Accordingly, the light paths of the light beam passing the photovoltaic layer are increased, and the possibility of the light beam absorbed by the photovoltaic layer is enhanced. In other words, the thin film solar cell of the present invention has higher photoelectric conversion efficiency. In addition, the present invention also provides a manufacturing method to form the above-mentioned thin film solar cell.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 schematically illustrates a cross-sectional view of an embodiment of a thin film solar cell according to the present invention.

FIG. 2 schematically illustrates a cross-sectional view of another embodiment of the thin film solar cell according to the present invention.

FIG. 3 schematically illustrates a cross-sectional view of yet another embodiment of the thin film solar cell according to the present invention.

FIGS. 4A to 4E schematically illustrate a process flow of an embodiment of manufacturing a thin film solar cell according to the present invention.

FIG. 5 schematically illustrates an embodiment of a method for forming a first adhesive layer according to the present invention.

FIGS. 6A to 6B schematically illustrate an embodiment of the method of forming a first adhesive layer according to of the present invention.

FIGS. 7A to 7C schematically illustrate an embodiment of a mesh method for forming a first adhesive layer according to the present invention.

FIG. 8 schematically illustrates a cross-sectional view of an embodiment of the thin film solar cell according to the present invention.

FIG. 9 schematically illustrates a cross-sectional view of another embodiment of the thin film solar cell according to the present invention.

FIG. 10 schematically illustrates a cross-sectional view of yet another embodiment of the thin film solar cell according to the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

FIG. 1 schematically illustrates a cross-sectional view of an embodiment of a thin film solar cell according to the present invention. Referring to FIG. 1, the thin film solar cell 200 of the present invention includes a transparent substrate 210, a first transparent conductive layer 220, a photovoltaic layer 230, a second transparent conductive layer 240, a first adhesive layer 250 and a reflective layer 260.

The transparent substrate 210 has a light incident surface 212 and a back surface 214 opposite to the light incident surface 212. This embodiment in which the transparent substrate 210 is a glass substrate is provided for illustration purposes, and is not construed as limiting the present invention. In other embodiments, the transparent substrate 210 can be a substrate with higher transparency, such as a plastic substrate or a flexible substrate.

The first transparent conductive layer 220 is disposed on the back surface 214 of the transparent substrate 210, as shown in FIG. 1. In this embodiment, the material of the first transparent conductive layer 220 can be indium tin oxide (ITO), indium zinc oxide (IZO), indium tin zinc oxide (ITZO), zinc oxide, aluminium tin oxide (ATO), aluminium zinc oxide (AZO), cadmium indium oxide (CIO), cadmium zinc oxide (CZO), gallium zinc oxide (GZO), fluorine tin oxide (FTO) or a combination thereof. Generally speaking, the first transparent conductive layer 220 is called a front contact as the position thereof is close to the light incident location.

The photovoltaic layer 230 is disposed on the first transparent conductive layer 220, as shown in FIG. 1. In this embodiment, the photovoltaic layer 230 can be a Group IV thin film, a III-V compound semiconductor thin film, a II-VI compound semiconductor thin film or an organic compound semiconductor thin film.

In details, the Group IV thin film is at least one of an amorphous silicon (a-Si) thin film, a microcrystalline silicon (μc-Si) thin film, an amorphous silicon germanium (a-SiGe) thin film, a microcrystalline silicon germanium (μc-SiGe) thin film, an amorphous silicon carbide (a-SiC) thin film, a microcrystalline silicon carbide (μc-SiC) thin film, a tandem I-V thin film (e.g. a tandem silicon thin film) and a triple I-V thin film (e.g. triple silicon thin film), for example. Further, the III-V compound semiconductor thin film can include a gallium arsenide (GaAs) thin film, an indium gallium phosphide (InGaP) thin film or a combination thereof. In addition, the II-VI compound semiconductor thin film can be a copper indium diselenide (CIS) thin film, a copper indium gallium diselenide (CIGS) thin film, a cadmium telluride (CdTe) thin film or a combination thereof. The organic compound semiconductor thin film is a mixture of poly(3-hexylthiophene) (P3HT) and PCBM, for example.

In other words, the structure of the photovoltaic layer 230 of this embodiment can be a photovoltaic structure used in a general amorphous silicon thin film solar cell, a microcrystalline silicon thin film solar cell, a tandem thin film solar cell, a triple thin film solar cell, a CIS thin film solar cell, a CIGS thin film solar cell, a GdTe thin film solar cell or an organic thin film solar cell.

The second transparent conductive layer 240 is disposed on the photovoltaic layer 230, as shown in FIG. 1. In this embodiment, the second transparent conductive layer 240 can include the material of the above-mentioned first transparent conductive layer 220, and the details are not iterated herein. The second transparent conductive layer 240 and the first transparent conductive layer 220 can have the same or different materials.

Referring to FIG. 1, the first adhesive layer 250 is disposed on the second transparent conductive layer 240, and the reflective layer 260 is disposed on the first adhesive layer 250. The surface of the first adhesive layer 250 in contact with the reflective layer 260 is a texture structure 255. In this embodiment, the material of the first adhesive layer 250 can be ethylene vinyl acetate (EVA), polyvinyl butyral (PVB), poly olefin or polyurethane (PU), for example. Further, the thickness of the first adhesive layer 250 of this embodiment is between 0.5 mm and 5 mm.

A light beam L1 enters the thin film solar cell 200 through the light incident surface 212, sequentially passes the transparent substrate 210, the first transparent conductive layer 220, the photovoltaic layer 230 and the second transparent conductive layer 240 and reaches the first adhesive layer 250. The light beam L1 passing the first adhesive layer 250 is reflected by the reflective layer 260 on the texture structure 255 and transmitted back to the photovoltaic layer 230, and the wavelength range of the reflected light beam L1 is substantially between 600 nm and 1,100 nm.

Specifically, when the external light beam L1 enters the thin film solar cell 200 through the light incident surface 212 of the transparent substrate 210 and sequentially passes the transparent substrate 210, the first transparent conductive layer 220 and the photovoltaic layer 230, a portion of the light beam L1 is absorbed by the photovoltaic layer 230, and another portion of the light beam L1 unabsorbed by the photovoltaic layer 230 passes the second transparent layer 240 and the first adhesive layer 250 and reaches the reflective layer 260 on the texture structure 255. Meanwhile, since the reflective layer 260 is disposed on the texture structure 255, a portion L2 of the light beam L1 is simultaneously reflected and scattered by the reflective layer 260 back to the photovoltaic layer 230, wherein the wavelength range of the light beam L2 is substantially between 600 nm and 1,100 nm. In this embodiment, the light beam L2 is red light, near-infrared light or far-infrared light, for example.

In details, the light beam L1 is perpendicularly incident to the surface 234 of the photovoltaic layer 230 and through the photovoltaic layer 230, and the light beam L1 unabsorbed by the photovoltaic layer 230 enters the first adhesive layer 250 and is reflected by the texture structure 255 or the reflective layer 260. Thereafter, the reflected light beam L2 is incident to the surface 234 of the photovoltaic layer 230 again, and the inclined angle θ between the reflected light beam L2 and the surface 234 of the photovoltaic layer 230 is less than 90 degrees. Accordingly, as compared with the light beam L1 perpendicularly passing the photovoltaic layer 230, the reflected light beam L2 has more light paths passing the photovoltaic layer 230, so that the possibility of converting solar energy to electron-hole pairs in the photovoltaic layer 230 is increased, and the total photoelectric conversion efficiency is further improved.

In other words, the reflective layer 260 is mainly for reflecting the light beam L2 having a wavelength range substantially between 600 nm and 1,100 nm in the light beam L1 back to the photovoltaic layer 230, so that the light beam L2 is absorbed by the reflective layer 260 again to improve the total photoelectric conversion efficiency. Further, the reflective layer 260 on the texture structure 255 also has the texture structure topography, so that the reflected light beam L2 is transmitted back to the photovoltaic layer 230 in a disorder manner. Therefore, the light paths of the light beam L2 in the photovoltaic layer 230 are increased, the possibility of the light beam L2 absorbed by the photovoltaic layer 230 is enhanced, and the total photoelectric conversion efficiency of the thin film solar cell 200 is further improved.

Specifically, the shape of the texture structure 255 of this embodiment is an irregular shape, for example. However, the present invention is not limited thereto. The shape of the texture structure 255 can be a vertical-stripe shape, a stripe shape, a horizontal-stripe shape, a grid shape, a rhombus shape, a honeycomb shape or a mosaic shape. Further, the texture structure 255 can be designed as a regular or irregular arrangement.

Moreover, the thin film solar cell 200 of this embodiment further includes a second adhesive layer 270 and an opposite substrate 280. The second adhesive layer 270 is disposed on the reflective layer 260. The opposite substrate 280 is disposed on the second adhesive layer 270 and opposite to the transparent substrate 210. In this embodiment, the opposite substrate 280 can be the substrate of the above-mentioned transparent substrate 210, and the details are not iterated herein. The opposite substrate 280 can be the same as or different from the transparent substrate 210.

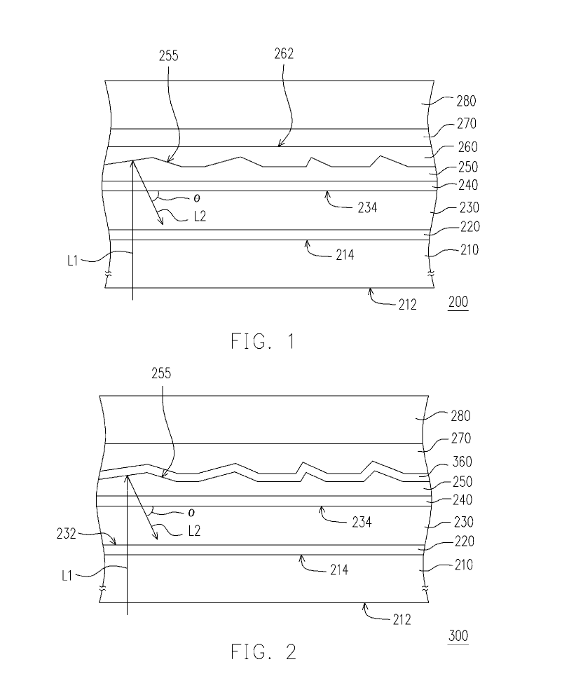

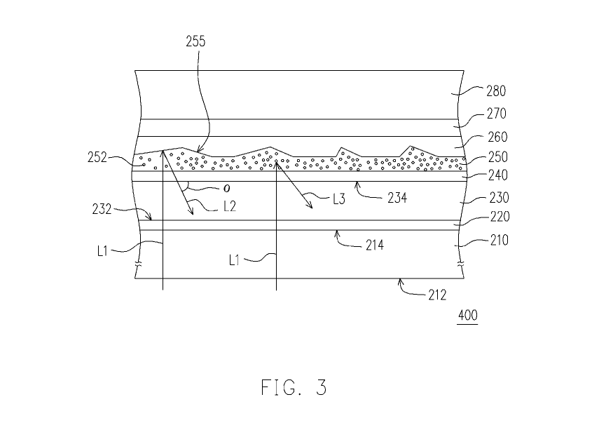

In the embodiment as shown in FIG. 1, the surface 262 of the reflective layer 260 away from the texture structure 255 is a planar surface, for example. The shape of the reflective layer 260 is provided only for illustration purposes, and is not construed as limiting the present invention. In another embodiment, referring to the thin film solar cell 300 in FIG. 2, the reflective layer 360 is conformal to the texture structure 255.

Further, the material of the reflective layer 260 of this embodiment can be one or more materials selected from the group consisting of a lead paint, a metal, a metal oxide and an organic material, so that the light beam L2 having a wavelength range substantially between 600 nm and 1,100 nm can be reflected back to the photovoltaic layer 230. In this embodiment, the reflected light beam L2 is a red light, a near-infrared light or a far-infrared light, for example. That is, the utilization rate of the light with wavelengths greater than the red light range is enhanced. It is appreciated by persons skilled in the art that the material of the reflective layer 260 can be selected upon the circumstances, so as to enhance the utilization rate of the light with a required wavelength range.

FIG. 3 schematically illustrates a cross-sectional view of another embodiment of the thin film solar cell according to the present invention. Referring to FIG. 3, the thin film solar cell 400 has most of the components of thin film solar cell 200. The same components are donated by the same reference numerals, and the details are not iterated therein.

Particularly, in the thin film solar cell 400, the first adhesive layer 250 further includes a plurality of particles 252 distributed therein, and a portion L3 of the light beam L1 is reflected by the plurality of particles 252 and transmitted back to the photovoltaic layer 230. Herein, the wavelength range of the light beam L3 reflected by the plurality of particles 252 is substantially between 600 nm and 1,100 nm. In-short, the light beam L1 entering the first adhesive layer 250 can be refracted or reflected by the plurality of particles 252 in the adhesive layer 250, so that the light paths passing the photovoltaic layer 230 are increased, and the light utilization rate of the light beam L1 is accordingly enhanced.

In view of the above embodiments, the first adhesive layer 250 in the thin film solar cells 200, 300 and 400 has the texture structure 255, so as to reflect the light beam L1, increase the light paths of the light beam L2 passing the photovoltaic layer 230, and further enhance the light utilization rate. Particularly, the material of the reflective layers 260 and 360 can be appropriately selected to combine with the texture structure 255, so that the light with a required wavelength range can be reflected back to the photovoltaic layer 230 and utilized. Therefore, each of the thin film solar cells 200, 300 and 400 can have higher photoelectric conversion efficiency.

The manufacturing method of the thin film solar cell 200 is described in the following.

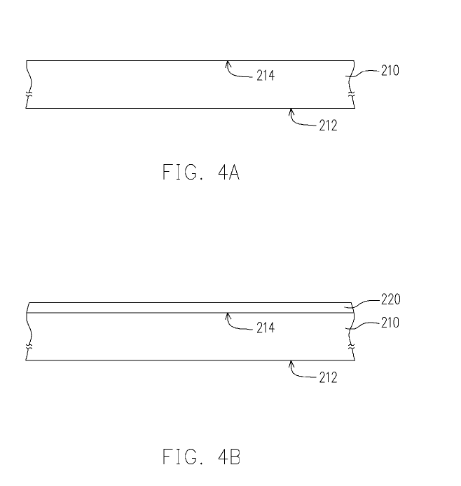

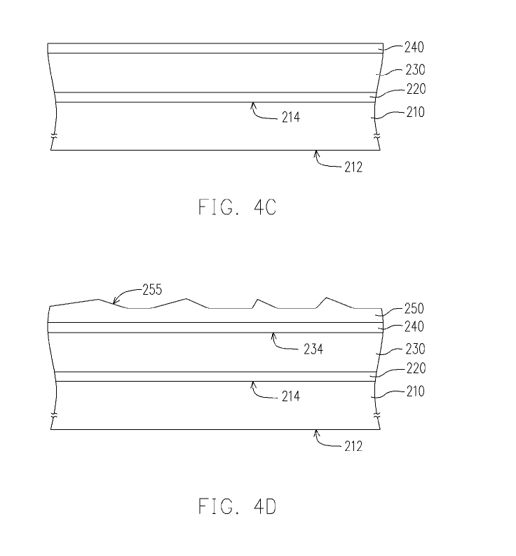

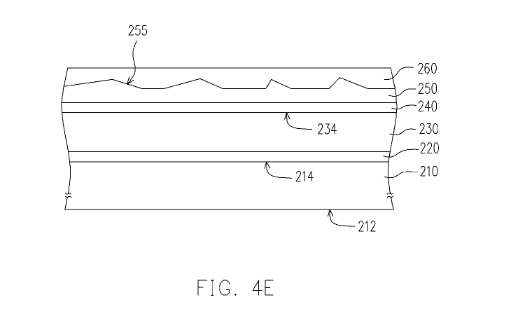

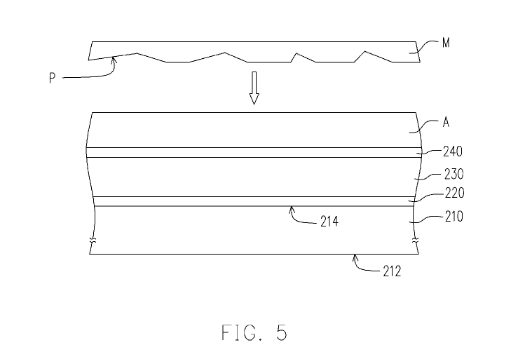

FIGS. 4A to 4E schematically illustrate a process flow of an embodiment of manufacturing the thin film solar cell according to the present invention. Referring to FIG. 4A, a transparent substrate 210 having a light incident surface 212 and a back surface opposite 214 to the light incident surface 212 is provided. In this embodiment, the transparent substrate 210 is a glass substrate, for example.

Referring to FIG. 4B, a first transparent conductive layer 220 is formed on the back surface 214 of the transparent substrate 210. In this embodiment, the material of the first transparent conductive layer 220 can be the material of the above-mentioned transparent conductive layer. The method of forming the first transparent conductive layer 220 is by performing a sputtering process, a metal organic chemical vapour deposition (MOCVD) process or an evaporation process, for example.

As shown in FIG. 4B, a photovoltaic layer 230 is formed on the first transparent conductive layer 220. In this embodiment, the method of forming the photovoltaic layer 230 is by performing a radio frequency plasma enhanced chemical vapour deposition (RF PECVD) process, a vary high frequency plasma enhanced chemical vapour deposition (VHF CVD) process or a microwave plasma enhanced chemical vapour deposition (MW PECVD) process, for example.

Referring to FIG. 4C, a second transparent conductive layer 240 is formed on the photovoltaic layer 230. In this embodiment, for example, the method of forming the second transparent conductive layer 240 is by performing the above-mentioned sputtering process, MOCVD process, or evaporation process, and the material of the same is the material of the above-mentioned transparent conductive layer, and the details are not iterated herein.

Referring to FIG. 4D, a first adhesive layer 250 having a texture structure 255 is formed on the second transparent conductive layer 240. In this embodiment, the method of forming the first adhesive layer 250 on the second transparent conductive layer 240 includes a stamping process. The stamping process includes the following steps. First, as shown in FIG. 5, an adhesive material layer A is blanket-formed on the second transparent conductive layer 240. The adhesive material layer A can include the material of the above-mentioned first adhesive layer 250, for example.

Thereafter, a die M having a texture pattern P is stamped on the adhesive material layer A, so as to form the first adhesive layer 250 having the texture structure 255, as shown in FIG. 4D. Herein, since the adhesive layer 250 has an adhesive property, the die M cannot be separated from the first adhesive layer 250 easily. Or, after the die M is separated from the first adhesive layer 250 by a period of time, the first adhesive layer 250 tends to be smooth and the texture structure 255 is disappeared. To avoid the above-mentioned problems, in some embodiments, an appropriate releasing agent is coated on the texture pattern P of the die M in advance, or the adhesive material layer A is previously doped with an appropriate releasing agent, so that the die M can be separated from the first adhesive layer 250 easily. Further, in some embodiments, a thermosetting material or a UV-curing material can be selected as the material of the adhesive material layer A. After the first adhesive layer 250 having the texture structure 255 as shown in FIG. 4D is formed by using the die M, a heating process or an ultraviolet radiation process is performed to cure the first adhesive layer 250, thereby fixing the shape of the texture structure 255.

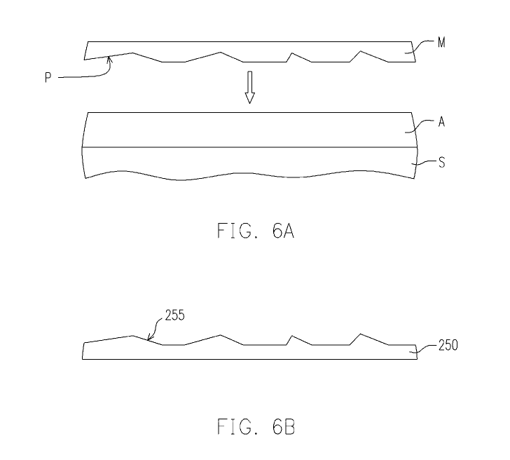

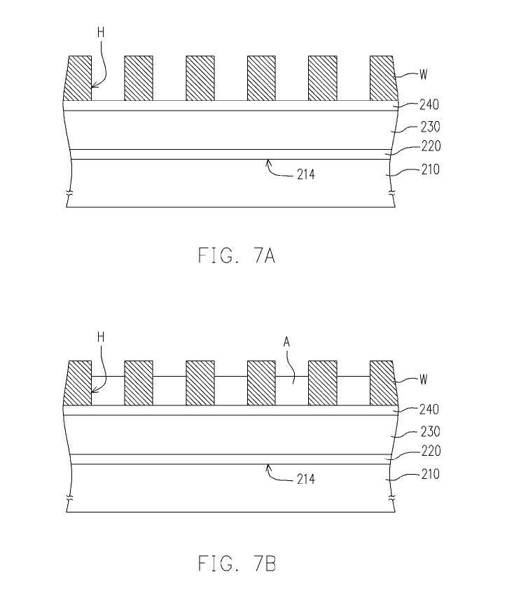

The method as shown in FIG. 5 is provided only for illustration purposes, and the present invention can adopt other methods to form the first adhesive layer 250. For example, in some embodiments, the method of forming the first adhesive layer 250 on the second transparent conductive layer 240 includes the following steps. First, as shown in FIG. 6A, an adhesive material layer A is provided. Herein, the adhesive material A is disposed on a platform S for performing the mechanical processing in the subsequent step.

Thereafter, a die M having a texture pattern P is stamped on the adhesive material layer A, so as to form the texture structure 255 on the surface of the adhesive material layer A, thereby obtaining the first adhesive layer 250 as shown in FIG. 6B. Afterwards, the first adhesive layer 250 is disposed on the second transparent conductive layer 240, so as to form the film layer structure as shown in FIG. 4D.

In details, after the die M is stamped on the adhesive material layer A to form the first adhesive layer 250 having the texture structure 255, the first adhesive layer 250 adhering to the die M is separated from the platform S. Thereafter, the side of the first adhesive layer 250 away from the texture structure 255 is stuck to the second transparent conductive layer 240. Afterwards, the die M is separated from the first adhesive layer 250 by heating or other suitable methods, so as to form the film layer structure as shown in FIG. 4D. In the method as shown in FIGS. 6A and 6B, the first adhesive layer 250 is formed by a mechanical stamping on the platform S, so as to avoid damages to other components of the solar cell caused by the mechanical stamping.

In addition, in some embodiments, a mesh process can be used to form the first adhesive layer 250, which is described in the following.

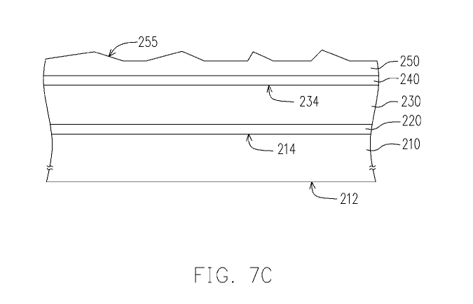

First, as shown in FIG. 7A, a die W having a mesh pattern is disposed on the second transparent conductive layer 240, wherein the mesh pattern has a plurality of openings H exposing the second transparent conductive layer 240. Herein, the mesh pattern of the die W can be designed according to the shape of the texture structure 255.

Thereafter, referring to FIG. 7B, an adhesive material layer A is formed on the die W, and a portion of the adhesive material layer A fills the openings H in contact with the second transparent conductive layer 240. Afterwards, the die W is removed to form the film layer structure as shown in FIG. 7C. It is noted that since the adhesive material layer A may generate a flow (e.g. elastic flow) after the die W is removed, a heating, cooling or curing process can be optionally performed, after the die W is removed, to cure the adhesive material layer A earlier, so as to form the first adhesive layer 250 having the texture structure 255.

The methods of forming the first adhesive layer 250 in FIG. 5, FIGS. 6A to 6B and FIGS. 7A to 7C are provided only for illustration purposes. The method of forming the first adhesive layer 250 is not limited by the present invention.

Referring to FIG. 4E, a reflective layer 260 is formed on the first adhesive layer 250 covering the texture structure 255. The method of forming the reflective layer 260 can adopt the method of forming the first transparent conductive layer 220 or the second transparent conductive layer 240, and the details are not iterated herein.

In addition, the manufacturing method of the thin film solar cell of this embodiment further includes forming a second adhesive layer 270 on the reflective layer 260, and disposing an opposite substrate 280 on the second adhesive layer 270 and opposite to the transparent substrate 210, so as to package the transparent substrate 210 and the opposite substrate 280 to complete the thin film solar cell 200, as shown in FIG. 1. In this embodiment, the method of packaging the transparent substrate 210 and the opposite substrate 280 by using the second adhesive layer 270 is well known to persons skilled in the art, and the details are not iterated herein.

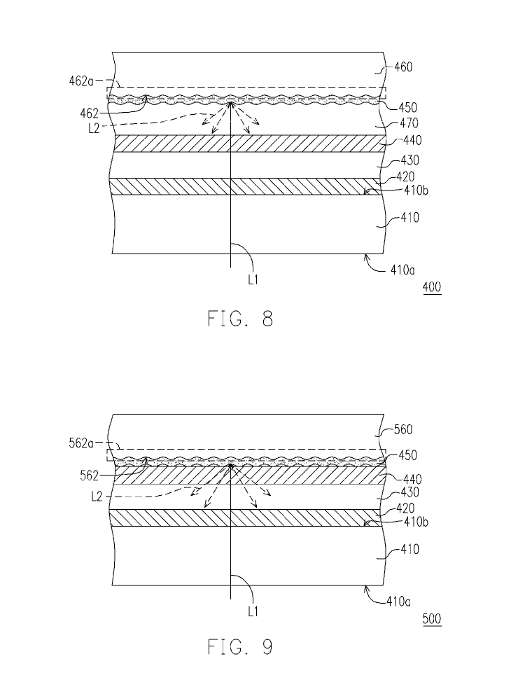

FIG. 8 schematically illustrates a cross-sectional view of an embodiment of the thin film solar cell according to the present invention. Referring to FIG. 8, the thin film solar cell 400 of this embodiment includes a transparent substrate 410, a first transparent conductive layer 420, a photovoltaic layer 430, a second transparent conductive layer 440, a light reflective layer 450 and a substrate 460.

The transparent substrate 410 has a light incident surface 410a and a back surface 410b opposite to the light incident surface 410a. This embodiment in which the transparent substrate 410 is a glass substrate is provided for illustration purposes, and is not construed as limiting the present invention. In an embodiment, the transparent substrate 410 can be a substrate with higher transparency, such as a plastic substrate (the material thereof is PC, PET or PES) or a flexible substrate.

The first transparent conductive layer 420 is disposed on the back surface 410b of the transparent substrate 410, as shown in FIG. 8. In this embodiment, the material of the first transparent conductive layer 420 can be indium tin oxide (ITO), indium zinc oxide (IZO), indium tin zinc oxide (ITZO), zinc oxide, aluminium tin oxide (ATO), aluminium zinc oxide (AZO), cadmium indium oxide (CIO), cadmium zinc oxide (CZO), gallium zinc oxide (GZO), fluorine tin oxide (FTO) or a combination thereof. Generally speaking, the first transparent conductive layer 420 is called a front contact as the position thereof is close to the light incident location.

The photovoltaic layer 430 is disposed on the first transparent conductive layer 420, as shown in FIG. 8. In this embodiment, the photovoltaic layer 430 can be the above-mentioned Group IV thin film, III-V compound semiconductor thin film, II-VI compound semiconductor thin film or organic compound semiconductor thin film, and the details are not iterated herein. In other words, the structure of the photovoltaic layer 430 of this embodiment can be a photovoltaic structure used in a general amorphous silicon thin film solar cell, a microcrystalline silicon thin film solar cell, a tandem thin film solar cell, a triple thin film solar cell, a CIS thin film solar cell, a CIGS thin film solar cell, a GdTe thin film solar cell or an organic thin film solar cell.

The second transparent conductive layer 440 is disposed on the photovoltaic layer 430, as shown in FIG. 8. In this embodiment, the second transparent conductive layer 440 can include the material of the above-mentioned first transparent conductive layer 420, and the details are not iterated herein. The second transparent conductive layer 440 and the first transparent conductive layer 420 can have the same or different materials.

Referring to FIG. 8, the substrate 460 has a surface 462 with a texture structure 462a thereon. The light reflective layer 450 is disposed on the surface 462 and conformal to the texture structure 462a, and the reflective layer 450 is disposed between the second transparent conductive layer 440 and the substrate 460. When a light beam L1 enters the thin film solar cell 400 through the light incident surface 410a, sequentially passes the transparent substrate 410, the first transparent conductive layer 420, the photovoltaic layer 430 and the second transparent conductive layer 440 and reaches the light reflective layer 450 on the texture structure 462a, at least a portion L2 of the light beam L1 having a wavelength range substantially between 600 nm and 1,100 nm is reflected by the light reflective layer 450 on the texture structure 462a.

In this embodiment, the material of the substrate 460 can be a transparent material or a non-transparent material. This embodiment in which the substrate 460 includes a transparent material is provided for illustration purposes. However, in other embodiments, the substrate 460 can be a non-transparent substrate, such as a metal substrate (e.g. copper foil or aluminium foil). Further, the light reflective layer 450 is conformal to the texture structure 462a, so that the light reflective layer 450 also has the texture structure topography, as shown in FIG. 8.

Specifically, when the external light beam L1 enters the thin film solar cell 400 through the light incident surface 410a of the transparent substrate 410 and sequentially passes the transparent substrate 410, the first transparent conductive layer 420 and the photovoltaic layer 430, a portion of the light beam L1 is absorbed by the photovoltaic layer 430, and another portion of the light beam L1 unabsorbed by the photovoltaic layer 430 passes the second transparent layer 240 and reaches the light reflective layer 450 on the texture structure 462a. Meanwhile, since the light reflective layer 450 is conformal to the texture structure 462a, a portion L2 of the light beam L1 is simultaneously reflected and scattered by the light reflective layer 450 back to the photovoltaic layer 430, wherein the wavelength range of the light beam L2 is substantially between 600 nm and 1,100 nm. In this embodiment, the light beam L2 is red light, near-infrared light or far-infrared light, for example.

In other words, the light reflective layer 450 is mainly for reflecting the light beam L2 having a wavelength range substantially between 600 nm and 1,100 nm in the light beam L1 back to the photovoltaic layer 430, so that the light beam L2 is absorbed by the photovoltaic layer 430 again to improve the total photoelectric conversion efficiency. Further, the light reflective layer 450 conformal to the texture structure 462a also has the texture structure topography, so that the reflected light beam L2 is transmitted back to the photovoltaic layer 430 in a disorder manner. Therefore, the light paths of the light beam L2 in the photovoltaic layer 430 are increased, the possibility of the light beam L2 absorbed by the photovoltaic layer 430 is enhanced, and the total photoelectric conversion efficiency of the thin film solar cell 400 is further improved.

In this embodiment, the material of the light reflective layer 450 can be one or more materials selected from the group consisting of a lead paint, a metal, a metal oxide and an organic material. The metal is selected from the group consisting of aluminium (Al), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), lanthanum (La), gadolinium (Gd), hafnium (Hf), tantalum (Ta), tungsten (W), rhenium (Re), osmium (Os), iridium (Ir), platinum (Pt), gold (Au), thallium (Tl), lead (Pb) and combinations thereof. The metal oxide is selected from the group consisting of indium oxide, tin oxide, silicon oxide, magnesium fluoride, tantalum oxide, titanium oxide, magnesium oxide, zirconium oxide, silicon nitride, aluminium oxide, hafnium oxide, Indium tin oxide (ITO), Cd₂SnO₄, Cd₂SnO₄ doped with copper, stannic oxide and stannic oxide doped with fluorine. The organic material can be a white dye or pigment.

In addition, in another embodiment (not shown), the light reflective layer 450 can be a polymer layer formed by a plurality of first polymer materials and a plurality of second polymer materials arranged alternately. The material of the first polymer materials is hydroxyl-acetylated poly (ethylene terephthalate) or a copolymer thereof, and the material of the second polymer materials is poly (ethylene-2,6-naphthalate) (PEN) or a copolymer thereof, for example.

The materials and types of the light reflective layer 450 described above are provided only for illustration purposes. The material of the light reflective layer 450 is within the scope of the present invention as long as it can reflect the light beam having a wavelength range between 600 nm and 1,100 nm.

Moreover, the thin film solar cell 400 further includes an adhesive layer 470 disposed between the light reflective layer 450 and the second transparent conductive layer 440. The adhesive layer 470 is mainly for packaging the thin film solar cell 400, as shown in FIG. 8. In this embodiment, the material of the adhesive layer 470 can be ethylene vinyl acetate (EVA), polyvinyl butyral (PVB), poly olefin or polyurethane (PU), for example.

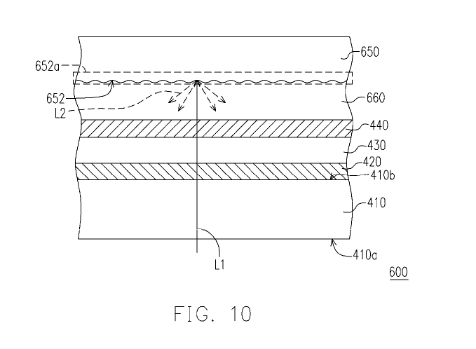

In another embodiment, the adhesive layer 470 is not required in the method of packaging the thin film solar cell 400. Rather, a transparent substrate 410 and a substrate 560 is directly assembled by a frame (not shown) to form the thin film solar cell 500 as shown in FIG. 9, wherein the above-mentioned first transparent substrate 420, photovoltaic layer 430 and second transparent conductive layer 440 are sequentially stacked on the transparent substrate 410, and the above-mentioned light reflective layer 450 is disposed on the substrate 560.

In the thin film solar cell 500, the structure thereof is similar to that of the thin film solar cell 400, and the difference between them only lies in the packaging methods. Therefore, the thin film solar cell 500 also has the above-mentioned advantages of the thin film solar cell 400, and the details are not iterated herein.

FIG. 10 schematically illustrates a cross-sectional view of a thin film solar cell according to yet another embodiment of the present invention. Referring to FIG. 10, the thin film solar cell 600 of this embodiment includes a transparent substrate 410, a first transparent conductive layer 420, a photovoltaic layer 430, a second transparent conductive layer 440 and a substrate 650. The transparent substrate 410, the first transparent conductive layer 420, the photovoltaic layer 430 and the second transparent conductive layer 440 have been described above, and the details are not iterated herein.

In the thin film solar cell 600, the substrate 650 has a surface 652 with a texture structure 652a thereon. The second transparent conductive layer 420 is disposed between the photovoltaic layer 430 and the substrate 650. When a light beam L1 enters the thin film solar cell 600 through the light incident surface 410b, sequentially passes the transparent substrate 410, the first transparent conductive layer 420 and the photovoltaic layer 430 and the second transparent conductive layer 440 and reaches the texture structure 652a on the substrate 650, at least a portion L2 of the light beam L1 having a wavelength range substantially between 600 nm and 1,100 nm is reflected by the texture structure 652a.

Specifically, when the external light beam L1 enters the thin film solar cell 600 through the light incident surface 410a of the transparent substrate 410 and sequentially passes the transparent substrate 410, the first transparent conductive layer 420 and the photovoltaic layer 430, a portion of the light beam L1 is absorbed by the photovoltaic layer 430, and another portion of the light beam L1 unabsorbed by the photovoltaic layer 430 passes the second transparent layer 440 and reaches the substrate 650 having the surface 652 with the texture structure 652a thereon. Meanwhile, if the substrate 650 is a non-transparent substrate, and the material thereof is suitable for at least a portion L2 of light beam L1 having a wavelength range substantially between 600 nm and 1,100 nm, the light beam L2 is reflected back to the photovoltaic layer 430 and absorbed by the photovoltaic layer 430 again, so as to improve the total photoelectric conversion efficiency. Further, the substrate 650 has the surface 652 with the texture structure 652a thereon, so that the reflected light beam L2 is transmitted back to the photovoltaic layer 430 in a disorder manner. Therefore, the light paths of the light beam L2 in the photovoltaic layer 430 are increased, the possibility of the light beam L2 absorbed by the photovoltaic layer 430 is enhanced, and the total photoelectric conversion efficiency of the solar cell 600 is further improved. In this embodiment, the light beam L2 is red light, near-infrared light or far-infrared light, for example.

In details, the material of the substrate 650 having the surface 652 with the texture structure 652a thereon can be a reflective material, such as metal, metal oxide or an organic material. The metal is selected from the group consisting of aluminium (Al), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), lanthanum (La), gadolinium (Gd), hafnium (Hf), tantalum (Ta), tungsten (W), rhenium (Re), osmium (Os), iridium (Ir), platinum (Pt), gold (Au), thallium (Tl), lead (Pb) and combinations thereof. The metal oxide is selected from the group consisting of indium oxide, tin oxide, silicon oxide, magnesium fluoride, tantalum oxide, titanium oxide, magnesium oxide, zirconium oxide, silicon nitride, aluminium oxide, hafnium oxide, Indium tin oxide (ITO), Cd₂SnO₄, Cd₂SnO₄ doped with copper, stannic oxide and stannic oxide doped with fluorine. The organic material can be a white dye or pigment.

In addition, in another embodiment (not shown), the reflective material can be a polymer layer formed by a plurality of first polymer materials and a plurality of second polymer materials arranged alternately. The material of the first polymer materials is hydroxyl-acetylated poly (ethylene terephthalate) or a copolymer thereof, and the material of the second polymer materials is poly(ethylene-2,6-naphthalate) (PEN) or a copolymer thereof, for example. The materials of the substrate 650 described above are provided only for illustration purposes. The reflective material of the substrate 650 is within the scope of the present invention as long as it can reflect the light beam having a wavelength range between 600 nm and 1,100 nm.

In this embodiment, to package the thin film solar cell 600, the transparent substrate 410 having the first transparent conductive layer 420, the photovoltaic layer 430 and the second transparent conductive layer 430 sequentially stacked thereon and the substrate 650 having the surface 652 with the texture structure 652a thereon can be stuck to each other by using an adhesive layer 660. That is, the adhesive layer 660 is disposed between the second transparent conductive layer 440 and the substrate 650, as shown in FIG. 10. Further, the material of the adhesive layer 660 can be the material of the above-mentioned adhesive layer 470, and the details are not iterated herein.

In an embodiment, when the material of the substrate 650 is a transparent material or a semi-transparent material, most of the light beam L1 can be totally reflected by using the different refraction indexes of the substrate 650 and the adhesive layer 660. In other words, if the texture structure 652a on the substrate 650 and the refraction index difference between the substrate 650 and the adhesive layer 660 are appropriately adjusted, at least a portion L2 of the light beam L1 having a wavelength range substantially between 600 nm and 1,100 nm is reflected back to the photovoltaic layer 430, so as to improve the total photoelectric conversion efficiency of the thin film solar cell 600.

In summary, the thin film solar cell of the present invention has a first adhesive layer and a reflective layer, and the surface of the first adhesive layer in contact with the reflective layer has a texture structure to reflect the light beam. Accordingly, the light paths of the light beam passing the photovoltaic layer are increased, and the photovoltaic layer can absorb more light to form electron-hole pairs. Particularly, the utilization rate of the light with wavelengths greater than the near-infrared light range is effectively enhanced. In other words, the thin film solar cell of the present invention has higher photoelectric conversion efficiency. Further, the present invention also provides a manufacturing method to form the above-mentioned thin film solar cell.

In addition, if the substrate of the present invention has a texture structure thereon and is a transparent substrate, a light reflective layer can be formed conformally on the texture structure. Accordingly, when the light beam sequentially passes the transparent substrate, the first transparent conductive layer, the photovoltaic layer and the second transparent conductive layer and reaches the light reflective layer, the light beam unabsorbed by the photovoltaic layer is reflected and scattered by the light reflective layer. Therefore, the light absorption efficiency of the photovoltaic layer is enhanced and the photoelectric conversion efficiency of the thin film solar cell is further improved.

If the substrate is a non-transparent substrate, the material thereof can be the material of the light reflective layer, so as to improve the photoelectric conversion efficiency of the thin film solar cell. Further, the materials of the adhesive layer and the substrate are appropriately selected to have a certain refractive index difference between them, so that the light beam unabsorbed by the photovoltaic layer is reflected, scattered and transmitted back to the photovoltaic layer, and thus, the photoelectric conversion efficiency of the thin film solar cell is improved.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A thin film solar cell, comprising:
a transparent substrate having a light incident surface and a back surface opposite to the light incident surface;
a first transparent conductive layer disposed on the back surface of the transparent substrate;
a photovoltaic layer disposed on the first transparent conductive layer;
a second transparent conductive layer disposed on the photovoltaic layer;
a first adhesive layer disposed on the second transparent conductive layer; and
a reflective layer disposed on the first adhesive layer, wherein a surface of the first adhesive layer in contact with the reflective layer is a texture structure,
wherein, a light beam enters the thin film solar cell through the light incident surface, the light beam is transmitted to the first adhesive layer by sequentially passing through the transparent substrate, the first transparent conductive layer, the photovoltaic layer and the second transparent conductive layer, the light beam passing through the first adhesive layer is reflected by the texture structure or the reflective layer and transmitted back to the photovoltaic layer, and a wavelength range of the reflected light beam is substantially between 600 nm and 1,100 nm.

2. The thin film solar cell of claim 1, further comprising:
a second adhesive layer disposed on the reflective layer; and
an opposite substrate disposed on the second adhesive layer and opposite to the transparent substrate.

3. The thin film solar cell of claim 1, wherein the reflective layer is conformal to the texture structure.

4. The thin film solar cell of claim 1, wherein a shape of the texture structure comprises a vertical-stripe shape, a stripe shape, a horizontal-stripe shape, a grid shape, a rhombus shape, a honeycomb shape or a mosaic shape.

5. The thin film solar cell of claim 1, wherein the texture structure is a regular or irregular arrangement.

6. The thin film solar cell of claim 1, wherein the first adhesive layer further comprises a plurality of particles distributed therein, and a portion of the light beam is reflected by the particles and transmitted back to the photovoltaic layer.

7. The thin film solar cell of claim 6, wherein a wavelength range of the portion of the light beam reflected by the particles is substantially between 600 nm and 1,100 nm.

8. The thin film solar cell of claim 1, wherein a material of the reflective layer comprises one or more materials selected from the group consisting of a lead paint, a metal, a metal oxide and an organic material.

9. A manufacturing method of a thin film solar cell comprising:
providing a transparent substrate having a light incident surface and a back surface opposite to the light incident surface;
forming a first transparent conductive layer on the back surface of the transparent substrate;
forming a photovoltaic layer on the first transparent conductive layer;
forming a second transparent conductive layer on the photovoltaic layer;
forming a first adhesive layer having a texture structure on the second transparent conductive layer; and
forming a reflective layer on the first adhesive layer covering the texture structure, wherein a light beam passing the first adhesive layer is reflected by the texture structure or the reflective layer and transmitted back to the photovoltaic layer, and a wavelength range of the reflected light beam is substantially between 600 nm and 1,100 nm.

10. The manufacturing method of claim 9, further comprising:
forming a second adhesive layer on the reflective layer; and
disposing an opposite substrate on the second adhesive layer to package the transparent substrate and the opposite substrate.

11. The manufacturing method of claim 9, wherein a method of forming the first adhesive layer on the second transparent layer comprises a stamping process.

12. The manufacturing method of claim 11, wherein the stamping process comprises:
forming an adhesive material layer on the second transparent conductive layer; and
stamping a die having a texture pattern on the adhesive material layer so as to form the first adhesive layer having the texture structure.

13. The manufacturing method of claim 9, wherein a method of forming the first adhesive layer on the second transparent conductive layer comprises:
providing an adhesive material layer;
stamping a die having a texture pattern on the adhesive material layer so as to form the texture structure on a surface of the adhesive material layer, thereby obtaining the first adhesive layer; and
disposing the first adhesive layer on the second transparent conductive layer.

14. The manufacturing method of claim 9, wherein a method of forming the first adhesive layer on the second transparent conductive layer comprises a mesh process comprising:
depositing a die having a mesh pattern on the second transparent conductive layer, wherein the mesh pattern has a plurality of openings exposing the second transparent conductive layer;
forming an adhesive material layer on the die, wherein a portion of the adhesive material layer fills the openings in contact with the second transparent conductive layer; and
removing the die to form the first adhesive layer having the texture structure.
